(19) United States
(12) Patent Application Publication
(10) Pub. No.: US 2003/0080772 A1
(43) Pub. Date: May 1, 2003

(54) Programmable compact motor drive module

(76) Inventors: Davide Giacomini, Boragaro T. se (IT); Enrico Bianconi, Borgaro T. se (IT)

Correspondence Address: OSTROLENK FABER GERB & SOFFEN, 1180 AVENUE OF THE AMERICAS, NEW YORK, NY, 100368403

(21) Appl. No.: 10/234,288

(22) Filed: Sep. 3, 2002

Related U.S. Application Data
(60) Provisional application No. 60/316,242, filed on Aug. 31, 2001.

(51) Int. Cl. G01R 31/36

(52) U.S. Cl. 324/771

(57) ABSTRACT

A modular power drive system includes a control module and a power module that are coupled together with standard connectors. The control module includes several interfaces for communication and a high speed processor to provide intelligent power control. The control module includes gate drivers, a power supply and current sense feedback circuitry for providing a closed loop power control. The power module includes power switches, power diodes and current sense resistors for driving a commanded output power level. The modular construction of the power driver permits separation of noise sources and noise sensitive components, and the construction of the control module board acts as a mechanical cover and electrical noise shield for the power module.

### RELATED APPLICATION

This application is based on and claims the benefit of U.S. Provisional Application Serial No. 60/316,242, filed Aug. 31, 2001, entitled Motor Drive Module, to which a claim of priority is hereby made.

### BACKGROUND OF THE INVENTION

1. Field of the Invention

This invention relates generally to power control modules, and relates more specifically to integrated intelligent programmable power control modules for multi-phase servo motor applications.

2. Description of the Related Art

Motor drive modules for driving and controlling multi phase electrical motors are well known. Simple applications for motor drivers include induction motors for applications where simple speed control is required. More complex and sophisticated motor drive modules are required for applications such as brushless motors or servo motors. Typically, a high performance servo motor requires sophisticated motor control that is both expensive and space consuming.

Integrated motor controllers that can provide a high level of performance in a limited amount of space are also known. However, such integrated motor drivers have a number of drawbacks with regard to cost and ease of implementation. Motor manufacturers often must spend large amounts of time and resources to develop motor drivers that can meet performance requirements in an integrated environment. Accordingly, it would be desirable to provide a flexible integrated motor driver that can be configured by a desire to meet requirements for particular motor applications.

It is often the case that an integrated motor driver will incorporate intelligence in its design to permit flexible applications for the driver. Such intelligent, integrated motor driver usually incorporates an intelligent power module, IGBTs and free wheeling diodes, gate drivers and sensing/feedback devices. Because of the difficulties presented by integrating all these features while maintaining high performance, the various devices are often provided in separate packaging to provide adequate noise immunity and environmental protection for the various component items. The separate packaging and relatively long cables needed to connect the separate packages introduce difficulties with large space requirements, increased costs and signal reflections and noise in the cables connecting the various devices and the motor, for which compensation must be provided.

### SUMMARY OF THE INVENTION

In accordance with the present invention, an intelligent and compact motor drive module is provided that forms a complete and flexible motor drive system. The motor drive system can be used to control a power inverter formed with six IGBTs and free wheeling diodes to drive a motor, for example. The motor drive system is composed of two separate modules mated together with standard type connections. The two separate modules include control and power functions, respectively.

The control module includes voltage monitoring, temperature and current output sensing, a high speed digital signal processor (DSP). In addition, a communication link interface is provided between the DSP and a local host computer, for example, thereby realizing a programmable communication interface. For example, software can be installed to the DSP through the communication link, which also offers the flexibility of data exchange for system monitoring and fault protection. The communication link can be an isolated serial port that can carry protocols related to a controller area network (CAN), serial communication interface (SCI) and serial peripheral interface (SPI). The communication link can also be made to operate in asynchronous or synchronous made, for example, for use with standard PC interfaces. In addition, feedback signals such as incremental encoder inputs can be applied through the synchronous isolated serial port.

The power module houses all the power components including the IGBTs and power diodes. Current sense resistors are also located in this module.

The control module itself is fully integrated with a high speed DSP controller with isolated inputs, a flyback power supply, current sense feedback and fault protection, in addition to providing control for the gate drivers of the power module. The control module has a very small footprint and provides natural shielding for noise sensitive components as a multilayer board. The control module is mounted directly over the power module and connected with standard connection pins and receptacles that permits the power drive module to be easily installed or replaced. In addition, upgrades to the control module can be easily carried out, either through programming, or simple replacement of the control module itself.

Control components that are less sensitive to noise are mounted on a lower side of the control module board, while components that are more sensitive to noise are located on a top side of the control module board to take advantage of the inherent shielding provided by the multilayer control module board construction. The control module board also acts as a cover for the power module to provide mechanical and electrical protection, while condensing the overall size of the intelligent power drive system. The shape and noise immunity features of the overall package permits the intelligent power drive system to be mounted very close to the driven motor, or even directly on the motor itself.

Between the power module and the control module a tiny layer of still air exists. This air layer reduces the heat transmission, due to missing air convection, between the power and control modules.

### BRIEF DESCRIPTION OF THE DRAWINGS

The present invention is described in greater detail below with reference to the accompanying drawings having reference numeral designators, in which:

FIG. 1 is a block diagram of the system incorporating the power module of the present invention;

FIG. 2 is a circuit diagram of the power module;

FIG. 3 is a perspective view of the module package structure including connection pins;

FIG. 4 shows a physical layout of the inverter power circuit within the package structure of FIG. 3;

FIG. 5 is a schematic block diagram of the control module of the present invention;

FIG. 6 is a schematic block diagram of the DSP with signal inputs and outputs;

FIG. 7 is a schematic block diagram of the flyback power supply incorporated into the control module of the present invention;

FIG. 8 shows a circuit schematic exemplifying power supplies for the overall power drive system;

FIG. 9 shows a schematic block diagram of the current sensing and fault detection features of the present invention;

FIG. 10 shows a schematic block diagram of the gate drivers according to the present invention; and

FIG. 11 shows a schematic block diagram for voltage protection features according to the present invention.

### DETAILED DESCRIPTION OF THE PREFERRED EMBODIMENTS

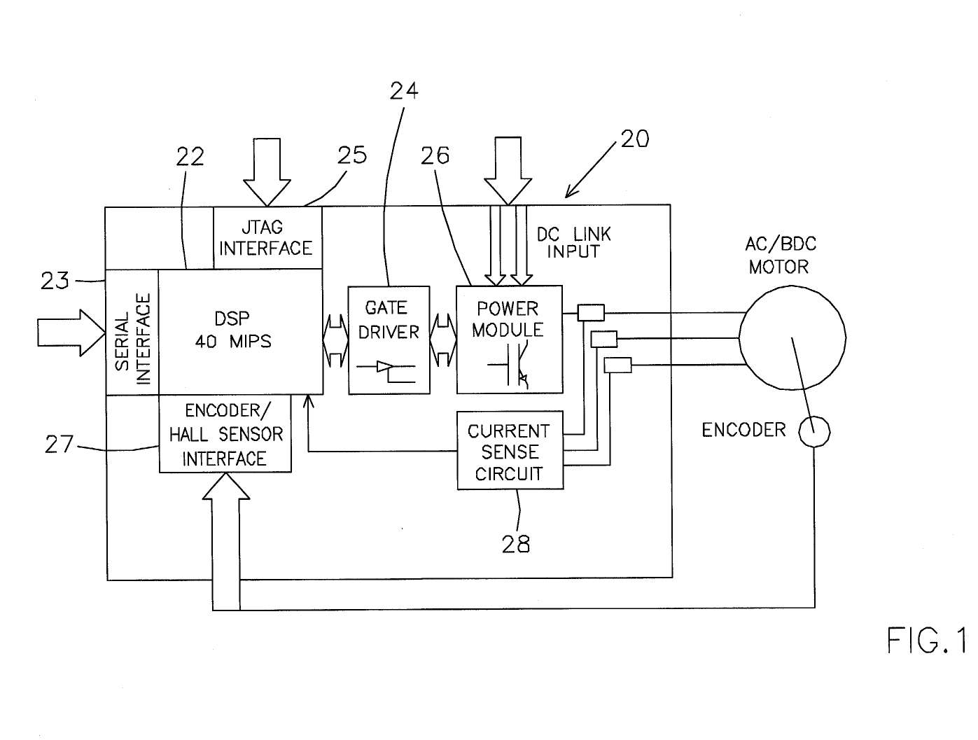

Referring now to FIG. 1, the overall motor drive module is shown generally as system 20. System 20 is composed of a DSP 22, a gate driver 24 and a power module 26. Gate driver 24 provides an interface between DSP 22 and power module 26 to translate control signals from DSP 22 to operate power switches in power module 26.

DSP 22 includes a number of interfaces for control and feedback signals. Serial interface 23 provides a communication link between DSP 22 and an external host. A serial interface 23 can be used to provide programming instructions to DSP 22 as well as communicating data between system 20 and a connected host computer. A communication link need not be connected directly to a host computer, but rather can form a node on a network to permit addressable control protocols.

A JTAG connector interface 25 permits direct access and debugging capability for DSP 22. JTAG interface 25 is standard and typically provides no isolation or signal conditioning. Feedback interface 27 provides a connection for encoder or Hall effect sensors reflecting the state of motor operation. System 20 also includes a current sense circuit 28 that provides feedback information of current delivered to the motor. It should be apparent that while the embodiment shown in FIG. 1 is for a motor control, any type of power control can be realized with the present invention where a power inverter is used.

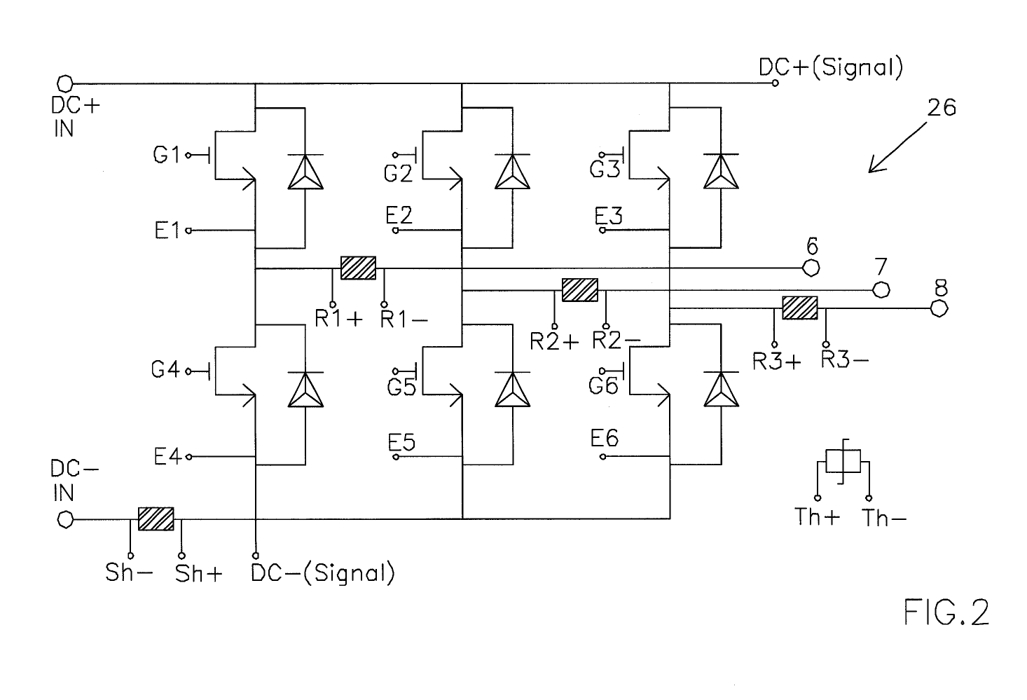

Referring now to FIG. 2, the components included in power module 26 are illustrated. Each leg of the power output is an assembly of a pair of IGBTs, each of which is in parallel with a free wheeling power diode. Current sense resistors R1, R2, and R3 illustrated on each of the legs providing output power. The signals from current sense resistors R1, R2 and R3 are provided to the current sense circuitry 28 (FIG. 1) for conditioning and delivery to DSP (FIG. 1) 22 to provide a close loop current control. Power module 26 also includes a current sense resistor SH connected on the DC minus input line to sense overcurrent conditions between switches for a given leg.

The components in power module 26 have the exemplary ratings of 1200 V for IGBT collector emitter voltage, 50A for IGBT continuous collector current at 100° C., 1200 V diode reverse breakdown voltage, 50A for diode continuous forward current at 100° C. and 2 milliohms for the sensing resistors. Power module 26 is maintained as a separate module from the drive control module, which permits a natural separation of power devices and noise sensitive control elements. The two modules are mated together through standard connector devices to permit easy removal of the drive control module without disassembling the power module. This feature permits easy system upgrades or configuration changes to the drive system. Between the power module and the control module a tiny layer of air still exists. This air layer reduces the heat transmission, due to missing air convection, between the power and control module.

Power module 26 incorporates IGBT power transistors that are matched with the accompanying free wheeling power diodes, both from International Rectifier Corporation. These devices do not need a negative gate voltage to turn off completely, and have a substantially reduced tail effect in comparison with other competitive devices. By utilizing the superior operating characteristics of these switches, the gate driving stage of the motor drive control can be further simplified. Power module 26 also features highly precise sensing resistors R1, R2 and R3, one in each of the three output phases, to provide precise motor current sensing. Resistors R1, R2 and R3 also provide short circuit protection by sensing current overloads. A current sense resistor SH is also provided on the DC bus negative line to provide further protection for components against power surges and short circuits.

The resistors used for current sensing can be specially designed precise resistors that can be trimmed to about 1% accuracy and formed on the power module using semiconductor processing techniques. In addition, an intelligent current sensing chip can be used in connection with the current sense resistors. Such a chip provides high precision current measurements and would be less sensitive to temperature changes. Power module 26 also includes a thermal sensor TH to provide temperature feedback from the power module to assist in improving the accuracy of current measurements and determining operational parameters of power module 26.

The packaging of power module 26 is chosen to be standardized for easy and straightforward connection with the control module. In addition, the feedback and command signals between the control module and the power module maintain Kelvin points for greater sensitivity and precision. Thus, all emitter and resistor sensing points are independent of the power pack. This result provides the tremendous advantage of having all low power signals to and from the control module be unaffected by parasitic inductances and resistances that are inevitably present in the power module layout. The presence of the Kelvin points prevents compromising voltage spikes and levels seen on the inputs of DSP 22. The noise associated with the parasitic inductances and resistances in the power module would otherwise be difficult to filter with conditioning circuitry on the inputs of DSP 22.

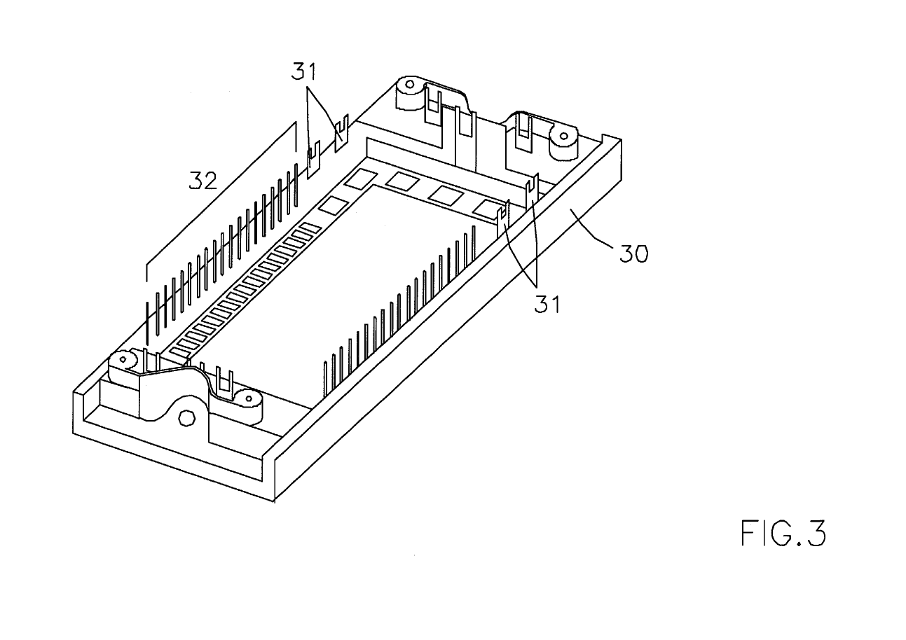

Referring now to FIG. 3, a perspective view of the drive module package is depicted generally as package 30. DC bus power pins 31 are shown as large pins on package 30 to handle high current spikes on those inputs. Signal pins 32 are also shown with a much smaller size, approximately half of that of power pins 31.

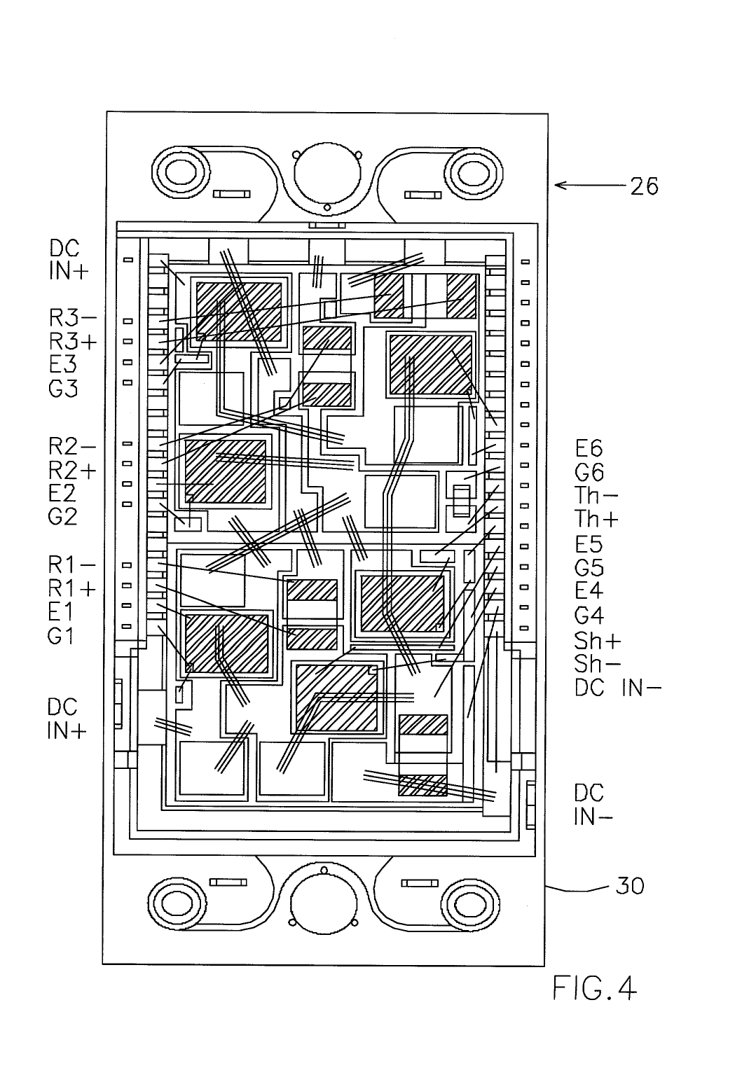

Referring now to FIG. 4, a component layout and connectivity for the power module 26 is illustrated. Current sense resistors R1, R2 and R3 are shown with their attendant connections. Also shown is current sensing resistor SH with attendant connections on the DC bus minus line.

Power module 26 has a thick copper base over which an alumina (Al₂O₃) substrate is prepared in addition to a 300 μm copper foil on both sides. IGBT and diode dies are directly soldered to the base and substrate and then bonded with 15 mil aluminum wire connections. Power module 26 is completely covered by a silicone gel to provide mechanical protection and electrical isolation.

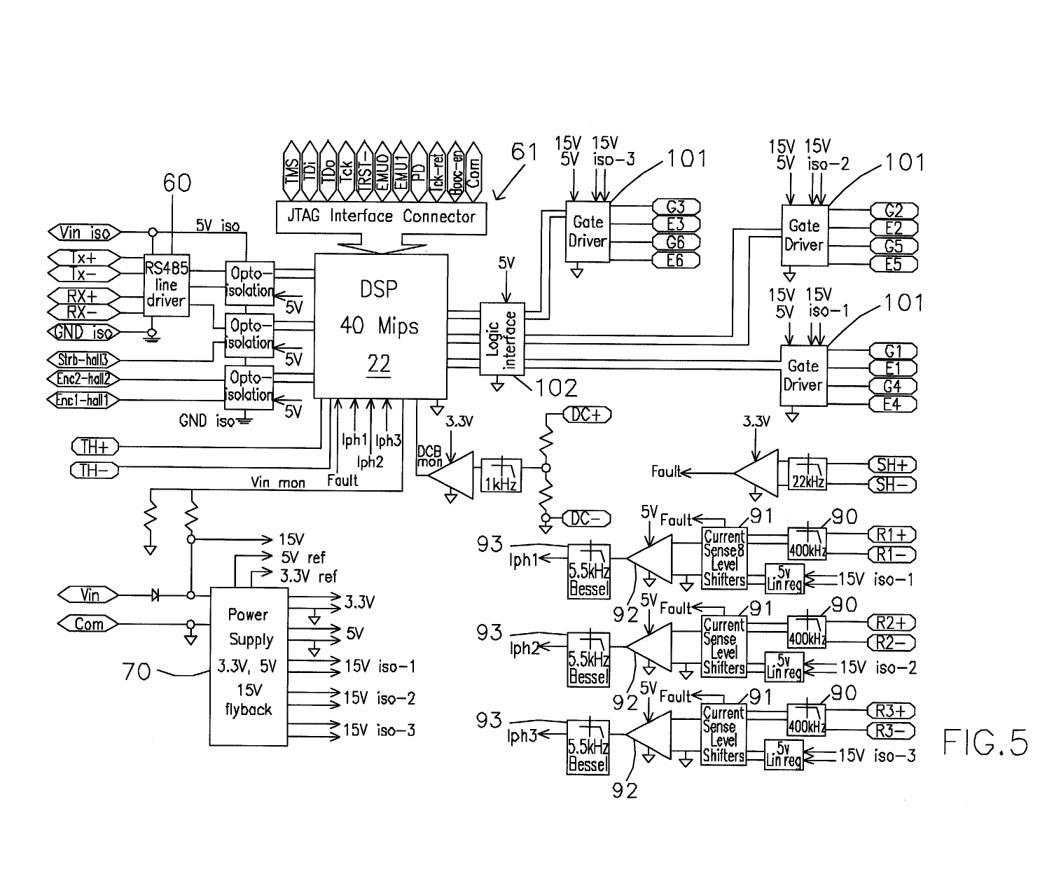

Referring now to FIG. 5, a schematic block diagram of the control module is shown. All the components representing the functions illustrated in the schematic block diagram of FIG. 5 are located on a drive control module board that is mounted directly over power module 26. Aside from providing the intelligent control for the drive module, the control board serves as a mechanical enclosure for power module 26. The control module board also offers noise protection for the low power, high speed components located on the top of the drive control board away from the typically noise producing components of power module 26. The drive control board utilizes surface mount technology to permit both sides of the drive control board to be used for component mounting. Accordingly, DSP 22 has pins that extend laterally from the chip, so that no pins extend through the board to remove valuable layout space. The drive control board components are discussed below as five separate functional blocks:

DSP 22 and interface connections;

flyback power supply;

signal interface and conditioning and fault protection;

gate drivers; and

DC bus and input voltage feedback.

Each of these functional blocks is discussed separately below.

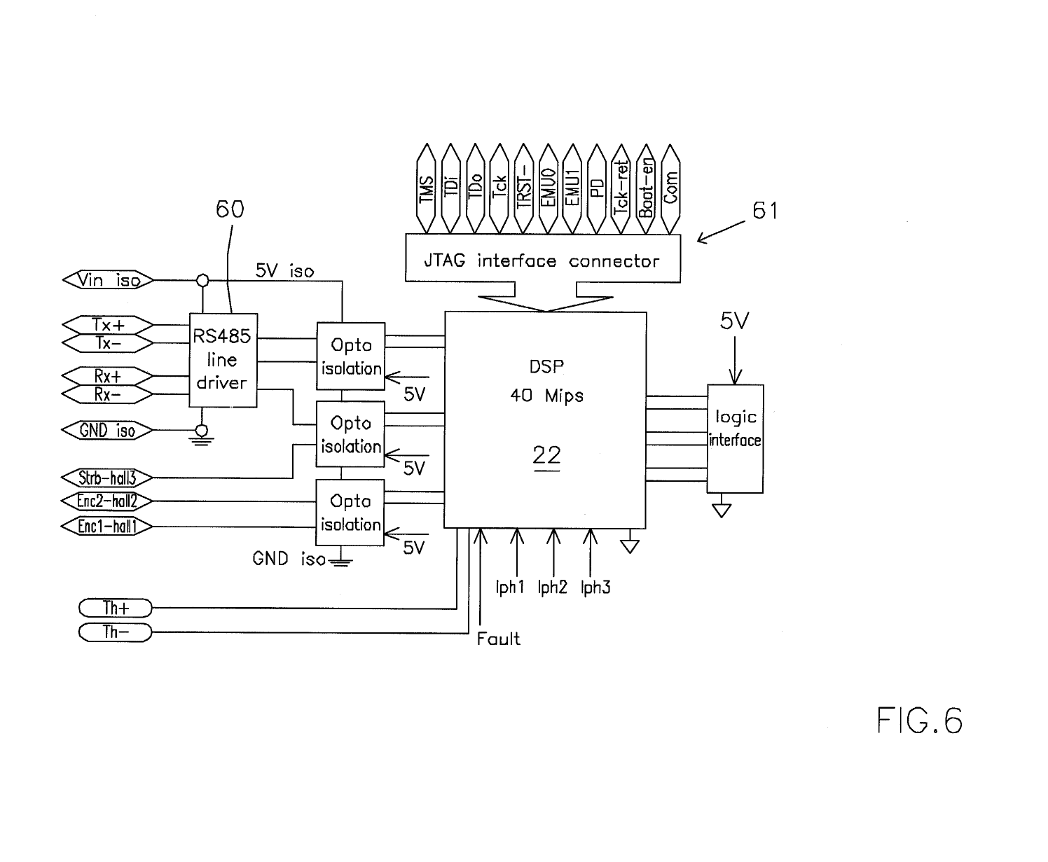

Referring now to FIG. 6, DSP 22 is illustrated with various interfaces for communication and control. DSP 22 is itself an improved processor for motor drive applications with a number of improved features. The operational characteristics of the chip used for DSP 22, from Texas Instruments, is illustrated below in Table 2 in comparison with a previous model of the chip.

TABLE 2
TMS320LF2406A vs TMS320F240

| | ‘F2406 | ‘F240 |
|---|---|---|
| MIPS | 40 | 20 |
| RAM | 2.5 Kw | 544 w |
| Flash | 32 Kw | 16 Kw |
| ROM | — | — |
| Boot ROM | 256 w | — |
| Ext. Memory I/F | — | Yes |
| Event Manager | Yes | Yes |
| GP timers | 4 | 3 |
| CMP/PWM | 10/16 | 9/12 |
| CAP/QEP | 6/4 | 4/2 |
| Watchdog timer | Yes | Yes |
| 10-bit ADC | Yes | Yes |
| Channels | 16 | 16 |
| Conv. Time (min) | 500 ms | 6.6 μs |
| SPI | Yes | Yes |
| SCI | Yes | Yes |
| CAN | Yes | — |
| Digital I/O pins | 37 | 28 |
| Voltage range | 3.3 V | 5 V |

The operation characteristics of DSP 22 provide advantages and features that improve the overall system performance of the motor drive control. In particular, the increased speed of operation (40 MIPS) with the increased number of I/O pins, a Boot ROM and a facility to handle the CAN protocol improves the simplicity of design for the user and furthermore reduces development time. In addition, DSP 22 uses a reduced supply voltage of 3.3V, which finds greater compatibility on a global basis. While the particular type of DSP 22 is not important to the design, the flexibility of use and high functionality make it very suitable for the motor drive control of the present invention.

DSP 22 can accommodate three different serial interfaces including SCI, SPI and CAN protocol communication links. Optical isolation can be used for the serial interface to permit DSP 22 to be isolated from noise or voltage spikes on the serial communication links. Depending upon the protocol chosen, the maximum bit rate for asynchronous communication can reach 2.5 Mbps, while synchronous communication can reach speeds of 10 Mbps. In the embodiment shown in FIG. 6, an SCI interface is shown to permit simple connection with a standard computer serial port. A line driver 60 is provided to adapt the standard computer serial port voltage (RS232) to the 3.3V standard used in the motor drive control application (RS485 at 3.3V). A standard computer serial port can have a speed of 100 kbps per second, which is not enough to handle system control for high performance applications, but demonstrates sufficient control for variable frequency induction motors. In a situation where a brushless servo motor is used for variable torque and servo applications, a 1 Mbps communication rate is sufficient to transmit all information related to torque reference updates, feedback and fault protection signals. This communication rate assumes a maximum frame rate of 10 kHz with 100 bits per frame. The differential communication capability of line driver 60 permits the use of long connecting wires, so that the complete motor drive system can be located very close to the motor. By placing the drive control system near the motor, long and noisy three phase cable lines between the driver and the load are avoided to further improve the performance of the system.

DSP 22 also provides a JTAG port connection 61 for onboard programmability of DSP 22. The signals on JTAG connector 61 can be directly connected to the appropriate pins on DSP 22, thereby taking advantage of further reduced board area.

DSP 22 also provides analog to digital conversion (ADC) for analog inputs. Sixteen ADC inputs are provided, each one having a conversion time of 500 ns as shown in Table 2. Each of the 16 inputs are time shared for processing, so that a conversion time for all 16 inputs with updated data is approximately 8 μs.

High speed operation performance can be met by insuring a good voltage signal on each ADC input pin. The voltage applied to an ADC pin can be affected by capacitive loading determined by the circuitry of DSP 22. If DSP 22 is configured as the chip from Texas Instruments, the capacitive load on the ADC pins is approximately 20 pF. Accordingly, the needed current supplied to an ADC pin to avoid voltage dropout of higher than about ½ LSB, within 500 ns, can be easily calculated. An additional capacitor is inserted between the ADC input pin and ground to obtain the needed current input to avoid any significant voltage dropout. The calculation for the capacitor is provided by the following equation.

$$C min = 20 pF * \frac{( 3.20 - \frac{3.125 * {10}^{- 3}}{2} )}{\frac{3.125 * {10}^{- 3}}{2}} = 41 nF$$

In the embodiment of the present invention, a 47 nF capacitor is used for practical purposes. In addition to providing stability and high speed at the ADC input pins, the addition of the capacitor lowers impedance to ground and therefore increases the immunity to noise for each of these pins.

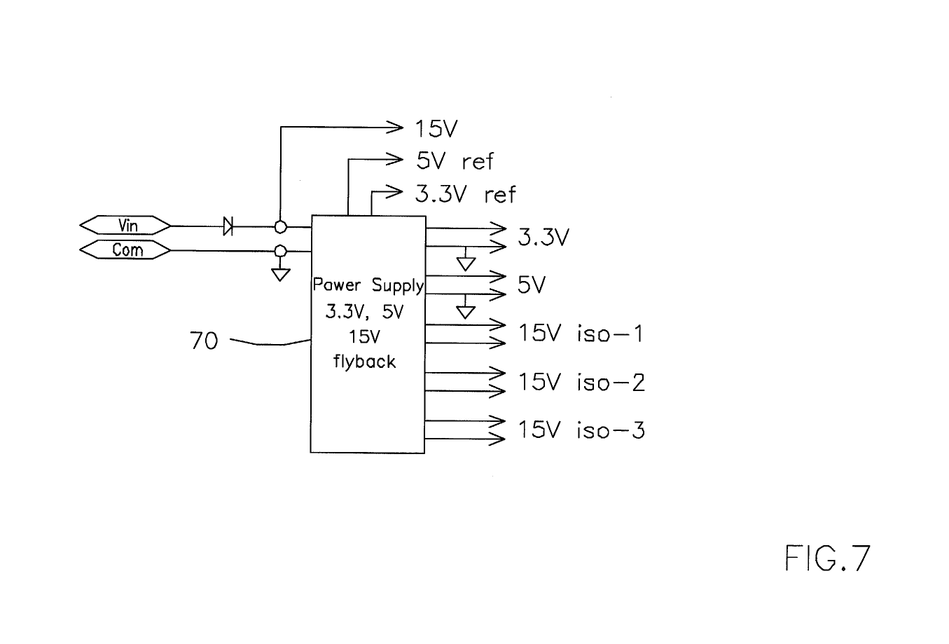

Referring now to FIG. 7, a flyback power supply used with the drive module according to the present invention is shown. Power supply 70 provides power for the floating stages of the drive module. The three 15V outputs for the floating stages are isolated from each other at a minimum of 1.5 kV. Power supply 70 also provides a single 5V and 3.3V output in reference to a common point. The 5V output supplies all low voltage electronics in the drive control module, while the 3.3V output supplies power to DSP 22. The 3.3V output is provided through a linear regulator, and is also provided to various logic and analog interfaces. The common reference of the 5V and 3.3V output is the negative line of the DC bus. DSP 22 is optically isolated through the serial communication link to avoid delays between DSP 22 and control logic devices. That is, no optical isolation is employed between DSP 22 and control logic, thereby increasing speed and overall system performance. The 15V input voltage shown in FIG. 7 is referenced directly to the negative line of the DC bus and supplies the low side gate driver stages. This direct power supply simplifies the design of the drive module and also permits the user to tailor the 15V supply for the application.

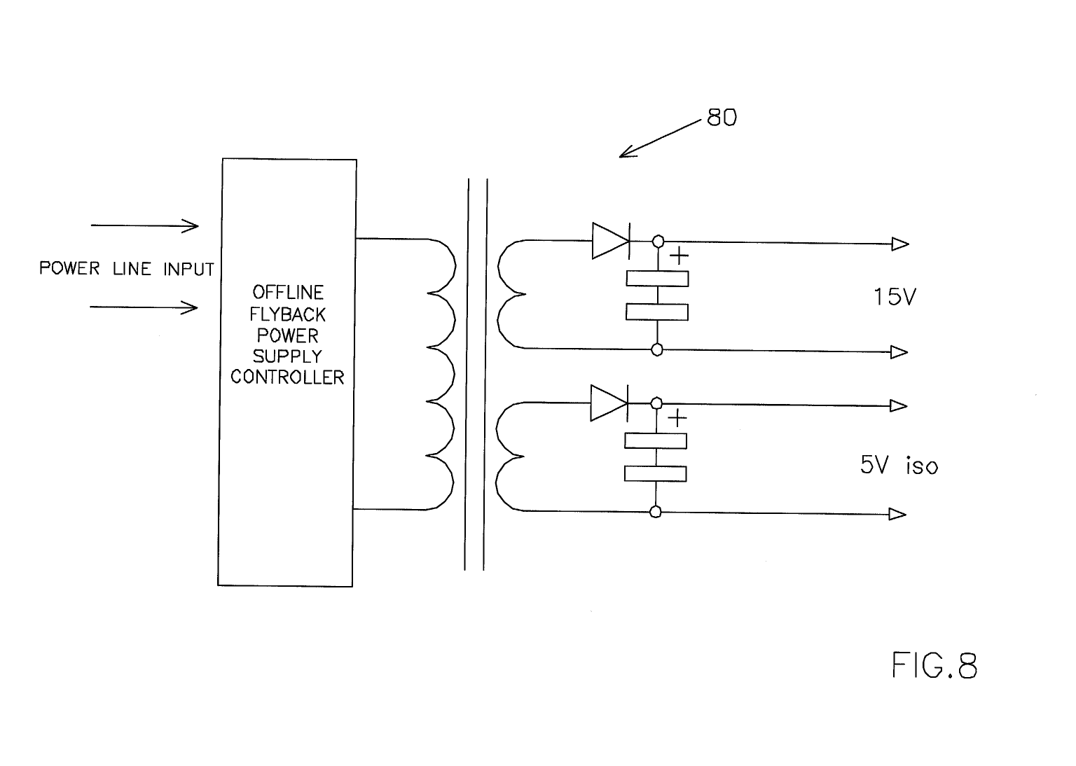

Referring to FIG. 8, an example of a 15V supply configuration is shown. Typically, a 5V power supply is provided for other electronic devices such as displays, sensors and microprocessors. This 5V supply can also be used for the 5V isolated supply for opto-couplers and line drivers. Because such a power supply is typical, the 15V supply can be established as an additional winding in the secondary side of the flyback transformer used to supply the 5V power source. The added winding only need be isolated from the 5V supply shown, typically with a minimum isolation of 1.5 kV. FIG. 8 illustrates such an example of a isolated power supply suitable for use with the present invention.

Referring again to FIG. 7, a 5V linear regulator is used to provide the reference voltage for the current sensing amplification and conditioning components. This 5V output is derived directly from the 15V input and provides a separate reference to avoid noise problems in measuring lines that can be caused by commutating electronics in the normal functioning of the system.

A 3.20V reference is derived from the 5V reference for use with the ADC included in DSP 22. The same linear regulator is used in power supply 70 as a starting point for all reference voltages. A precision operational amplifier, configured as a voltage follower is used in partitioning the 3.20V reference from the 5V reference. The use of the linear regulator as a starting point for all reference voltages permits the voltages to track and maintain overall precision, even in the presence of interfering noise and parasitic signals. For example, if the 5V linear regulator modulates over a temperature profile or in time, each of the derived references will continue to track and maintain overall precision. This feature also permits precision trimming of the power output to be conducted at a single point in the supply chain. For example, the conditioning circuitry, which can be an operational amplifier, for collecting the current sensing signals, can be adjusted as the single point of precision for power supply.

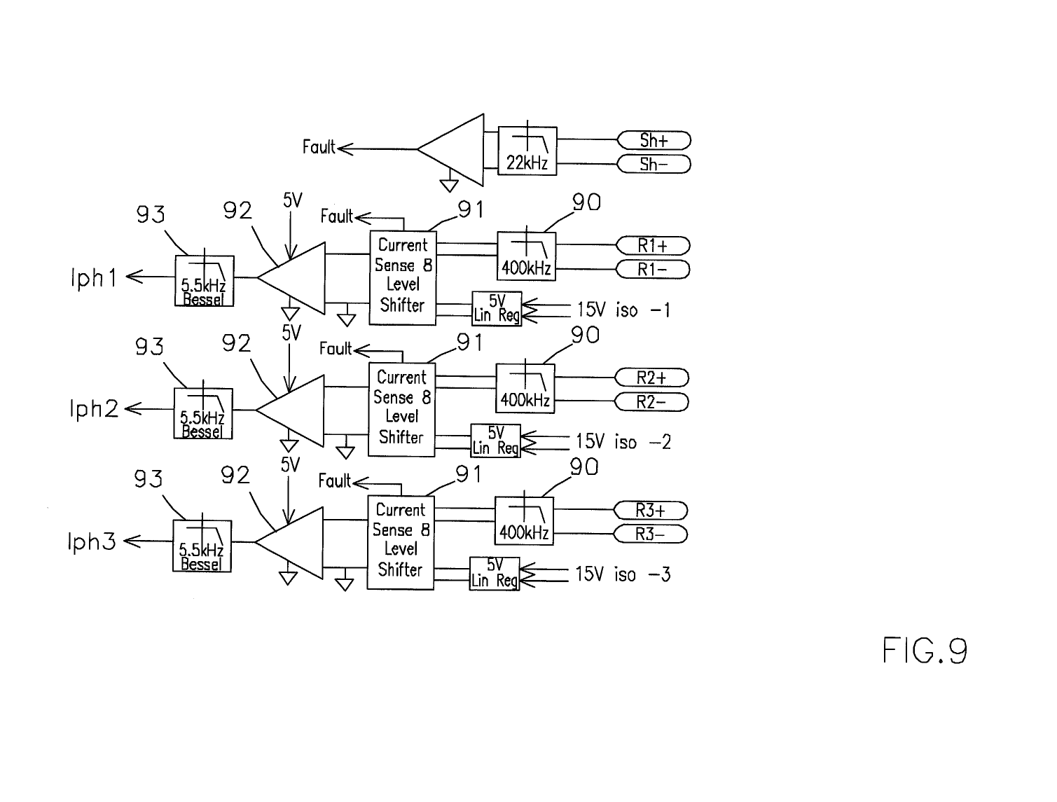

Referring now to FIG. 9, the current sensing interfaces, overcurrent protections and signal conditioning components are illustrated. These components and functions can determine performance critical to precision applications and thus provide an important feature of the present invention. Performance measured through current feedback has a direct impact on motor control performance in servo applications, including errors in current evaluation, measurement delay and overall system precision. The precision of the overall system can be affected by parameters such as scarce references or low numbers of significant bits derived from ADC conversions. These types of performance criteria, if not addressed appropriately, results in unwanted trembling and high frequency noise from the motor while running at low speeds or when a blocked shaft condition is encountered. These types of performance problems can be avoided by configuring the system with appropriate performance parameters. For example, the current sensing loop should meet the following criteria:

bandwidth≧3 kHz

latency≦15 μs−20 μs

An important performance factor that should not be overlooked is the significance of the information provided in the current feedback loop. If significant information is delayed, the closed loop current gain is typically lower than expected to provide desirable phase margins and avoid instability. The lower loop gain in turn can result in poor performance due to limited system precision for torque control. Typically, a hall effect sensor is used for current measurement to obtain the needed responsiveness for a precision system. Hall effect sensors can achieve closed loop parameters with 100 kHz of bandwidth while having a phase lag of only about 10°. However, the cost of a hall effect sensor is fairly high, and they have larger dimensions than is practical for the limited spaced available in the drive module or motor connection box. Accordingly, the system according to the present invention adopts a sensing resistor voltage dropout measurement that provides the needed precision for low current applications (100A-150A) with a reduced size and a lower cost. By incorporating current sense resistors in power module 26 according to the present invention, the sensing feedback can be accomplished in a compact manner, and the connections to the drive control module can be Kelvin point connections to further enhance measurement precision.

Current sensing resistors R1, R2 and R3 can be implemented as high precision and trimmable resistors that can be incorporated into the component board of power module 26 with known semiconductor processing techniques. These types of resistors can obtain about a 1% accuracy while providing a precision resistance in the milliohm range.

The voltage obtained across each sensing resistor is applied to an anti-aliasing filter 90 with a cutoff frequency of approximately 400 kHz. The output of the anti-aliasing filter 90 is provided to a current sense integrated circuit 91 that converts the sensed voltages to a standardized dynamic range voltage. For example, if a sensing resistor of 2 milliohms is used and the sensed current range is +/−100A than the dynamic range output is as follows:

−100A=0.0V

0.00A=2.5V

+100A=5.0V

The ADC inputs to DSP 22 have an external reference of 3.20V as discussed above. Accordingly, the current sense outputs are mapped to a 0-3.20V dynamic range, as well as being filtered to obtain an average current value. The mapping and filtering can be done in a single step, although illustrated in FIG. 9 as two separate components, op-amp 92 and external passive filter 93. The single step realization is a voltage control voltage source (VCVS) cell, such as a constant gain or Sallen-Key cell. The VCVS cell is configured so that the offset and gain can be trimmed with three onboard resistors. This configuration provides a single point for precision setting all current measurements in one simple step. Two SMD resistors are soldered in the op-amp input lines to recover the system offset, and a third resistor is used to re-center the damping factor 2ζ and the resonant angular frequency ω₀ of the second order filter.

The Sallen-Key cell is also flexible to permit implementation of any type second order low pass filter. For example, a second order Bessel filter with a 5 kHz pole frequency can be chosen for the low pass filter. The Bessel filter polynomials provide a technique for calculating a constant group delay within the bandpass frequencies to obtain a minimum waveform distortion in the output signal at up to almost twice the filter pole. That is, the group delay of the signal chain from the sensing resistor to the ADC input of DSP 22 is constant from about 0 to 5 kHz. A summary of current measurement performance is provided in Table 3.

TABLE 3
PI-IPM ™ Current Sensing Chain Typical Performances

| | Value | Units |
|---|---|---|
| Current range | +/−100 | A |
| Precision | 0.1 | % |
| Bandwdith at 10 degrees | 3 | kHz |
| Latency time | 15 | μs |

The resistors on the power module and the control module can be modified to adapt system parameters to desired applications. For example, the range of current sensed can be modified, the type of filter can be changed as well as the pole frequency, and thus permit operation at different levels. The ADC inputs on DSP 22 have a 10 bit granularity, meaning that in the embodiment of the present invention, the minimum measurable current step is approximately:

$$LSB = \frac{2 * 100}{{2}^{10}} = 0.1953 A$$

That is

1LSB≅195 mA

If the maximum current range is reduced, or the current sensing resistor value is modified, for example with low power modules, the minimum current step measurable would also be further reduced.

A feature of current sense IC 91 is an overcurrent fault output signal. When the sensed voltage across the current sense resistor reaches 250 mV, indicating an overcurrent level of approximately 25%, the attendant overcurrent fault output signal goes low. Because current sense IC 91 employs internal opto-couplers for noise immunity, there is a delay associated with the overcurrent fault signal of about 3 μs. However, this delay is short enough to permit DSP 22 to react within 10 μs, which is within the short circuit rating of the IGBTs. Accordingly, this overcurrent fault detection provides protecting for phase-to-ground and phase-to-phase short circuits. However, the overcurrent fault detection in current sense IC 91 does not detect crossthrough overcurrent conditions that are seen between two IGBTs of the same leg. Accordingly, a fourth sensing element, resistor SH, with the same resistive value as the other current sense resistors, is inserted in series with the negative line of the DC bus. The measured voltage across current sense resistor SH is then filtered with a 22 kHz passive filter to avoid false fault detections through induced voltage spikes. The filtered output is applied to an operational amplifier configured as a comparator and then provided to DSP 22 to handle sensed faults.

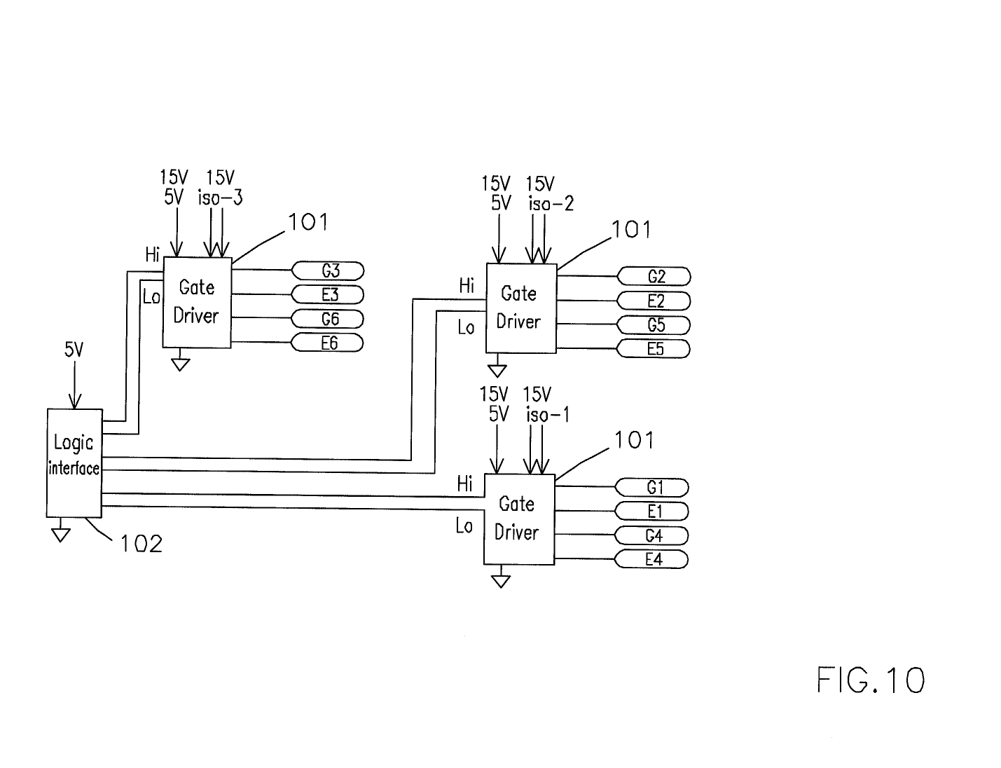

Referring now to FIG. 10, gate drivers 101 for switches on power module 26 are illustrated. Gate drivers 101 are responsible for correctly turning on and off all inverter IGBTs, avoiding cross conduction, preventing false turn on during commutations and avoiding dangerous propagation delays between input signals and output commands. Devices suitable for performing these tasks are readily available, such as the gate driver product IR2213 from International Rectifier Corporation. The gate driver is capable of 2A sink and source gate driving current. As discussed earlier, the IGBTs used in power module 26 do not require a negative gate drive voltage to completely turnoff. This feature of the IGBTs greatly simplifies the flyback power supply design to avoid the need of a center tapped transformer output, or the use of zener diodes, to create a central common reference for the gate drivers floating ground. The advantage of this configuration is the reduced requirement for board space that would otherwise be needed for providing two electrically floating traces for each output phase on the control module board. The use of only a single electrically floating line for each of the three phases decreases board space requirements while also avoiding the problems of potentially increased noise and isolation difficulties attendant with two floating lines for each output phase. Turn on and turn off times for the IGBTs can be modified using different gate resistor values. For example, a diode-resistor series in parallel with a single resistor can be used to modify gate turn on and turn off times separately.

Gate drivers 101 do not use opto-coupling for noise immunity, and therefore avoid the typical 1 μs delay that would otherwise impact the system control. Gate drivers 101 also provide level shifting to drive the IGBTs of power module 26. However, the selected components for gate drivers 101 have a 5V logic input signal range, which could not be driven directly with the logic output of DSP 22, which has a 3.3V logic level range. Accordingly, a logic interface 102 is inserted between DSP 22 and gate drivers 101 to adapt the logic level to the appropriate range. It is contemplated that gate drivers can be designed to accept a logic level range of 3.3V to thereby eliminate the need of logic interface 102.

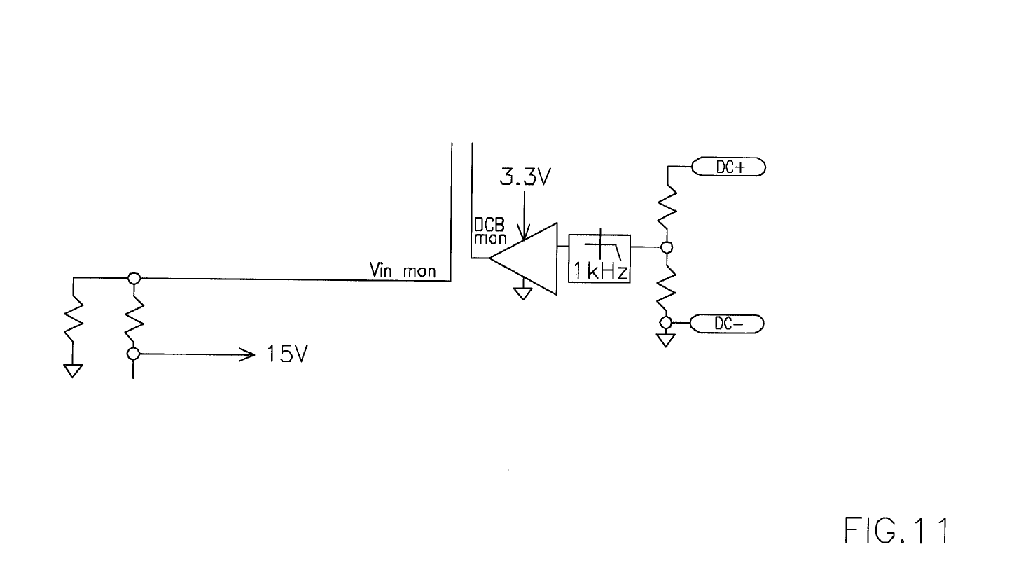

Referring now to FIG. 11, a circuit for monitoring the supply lines of Vin and the DC bus is illustrated. The external power supply of Vin is used for all electronics in the control module. Internal flyback power supply 70, illustrated in FIG. 7, maintains an undervoltage lockout to prevent the electronic components from operating when an insufficient supply voltage is present. This undervoltage lockout (UVLO) is set internally at a typical voltage of approximately 8.4V with a hysteresis of 0.8V. When the supplied input power is found to reach this level, flyback power supply 70 turns on and powers the components on the control module board. In addition, low side gate drivers are directly supplied from the Vin line, so that the low side gate drivers are responsible for their own UVLO. For the low side gate drivers, this voltage level is typically set at 8.5V, which is insufficient to properly drive the IGBTs. To adjust the voltage, a standard resistor divider is employed to obtain a lockout voltage level of between 10 and 18V before the IGBTs are permitted to start switching. This standard resistor divider configuration also inherently provides an overvoltage control.

The DC bus voltage is also monitored to obtain a high performance level, which is accomplished through another resistor divider network. However, the resistor divider network is operated at a high voltage on the drive control module, and therefore must be laid out and configured carefully to provide appropriate noise immunity. The resistor divider network illustrated in FIG. 11 provides a partition coefficient of 3.47 mV/V, which provides a maximum mapped voltage through the ADC, having a reference voltage of 3.20V, of:

$$VDCbus\_max = \frac{3.20}{3.47 * {10}^{- 3}} = 922 V$$

The output of the resistor divider network is filtered with a 1 kHz passive filter to avoid false fault detections on the DC bus due to voltage spikes that are inevitably present. The filtered voltage is supplied to an operational amplifier configured as a voltage follower to buffer the voltage signal before being supplied to an ADC input of DSP 22. This configuration permits a granularity in determining the DC bus voltage of:

$$1 LSB = \frac{922}{{2}^{10}} = 0.9 V$$

The motor drive system described is suitable for a number of applications including Brushless, Induction and Linear motors. The drive module includes a sophisticated computational engine that can be used to derive a number of sensor type estimates. Accordingly, such a device can be used in developing application in which sensors are not required.

The flexibility and packaging of the drive module system permits custom modification for desired applications, that can be further customized with applications specific software loaded into the DSP.

One of the major advantages provided by the construction of the control module is a number of conductive layers in the module board. The board design incorporates high voltage copper lines with appropriate spacing between components to reduce noise. Noise is further reduced by providing two internal layers in the drive control module board for a ground plane and Vin and 5V isolated supply voltages. Three layers, including a top and bottom layer, are used for low power signal interconnections. Another internal layer is used for high voltage floating lines for gate drivers and current sense devices. The layout of the board provides excellent noise immunity for low power signals while also providing high power routing and interconnection. Because of the noise shielding characteristics of the control module board, noise and temperature sensitive devices, such as the DSP and current sensing components, are placed on top of the board, away from the lower power module. Components that are not as sensitive to noise and temperature can be placed on the bottom side of the drive control module board, including gate drivers and the flyback power supply.

One source of noise that can be introduced to the high impedance analog lines is the inductive or capacitive coupling introduced through commutation between the positive and negative lines of the DC bus. This commutation can produce a voltage swing of about 500V. If any inductive or capacitive coupling occurs, the impact on system performance can be significant. Accordingly, the high impedance analog lines are carefully laid out in the drive control module board, and placed in a single internal layer to avoid any potential noise produced by coupling. In addition, the high impedance analog lines are laid out so that if the lines cross any other lines in a different layer, the lines are perpendicular to each other to reduce any crosstalk that may be likely to occur.

The position of the flyback power supply on the driver control module board is also important. The controller for the flyback power supply is switching at 200 kHz and therefore produces noise that can have an impact on sensitive devices such as the current sense components and the DSP. Accordingly, the flyback power supply is located in a corner of the drive control module board, at an opposite end from the DSP and spatially isolated as much as possible from the other analog circuitry.

The resulting intelligent power module provides high performance, for example, for servo motor drive applications, while maintaining very limited dimensions. The drive module is extremely flexible, programmable and is constructed to be modular for ease of replacement, repair or upgrade.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A programmable inverter drive module, comprising:
a processor programmable to accept inputs related to inverter operation and process the inputs to produce inverter control outputs for controlling the inverter;
a communication interface coupled to the processor for transferring information to and from the processor;
a current sense signal derived from current provided by the inverter under control of the processor; and
a conditioning circuit for conditioning the current sense signal and providing the conditioned signal to the processor to provide a closed loop converter control.

2. The module according to claim 1, wherein the inverter is separated from the processor and conditioning circuit.

3. The module according to claim 2, further comprising a shield separating the inverter and the processor and conditioning circuit.

4. The module according to claim 2, wherein the processor and conditioning circuit are located on a circuit board that is removably connected to the inverter.

5. The module according to claim 1, further comprising sensing resistors coupled to the output current of the inverter.

6. The module according to claim 1, further comprising a thermal sensor coupled to the inverter and capable of providing a thermal sense signal to the processor.

7. A power control module, comprising:
a control board including a signal processor, a communication interface coupled to the signal processor, circuitry for processing current sense signals indicative of output current and outputting the processed signals to the signal processor, a gate driver controlled by said signal processor and a power supply; and
a power module removably coupled to the control board and including a power switch driven by the gate driver to switch power to a load, a power diode in parallel with the switch and a current sense resistor for providing the current sense signal indicative of output current.

8. The module according to claim 7, wherein the switch turns off without the application of a negative voltage.

9. The module according to claim 7, further comprising a current sensing resistor on a negative line of a DC bus in the power module.

10. The module according to claim 7, further comprising a thermal sensor on the power module for providing a signal to the signal processor indicative of a temperature of the power module.

11. The module according to claim 7, further comprising Kelvin point connections between the control board and the power module.

12. The module according to claim 1, further comprising an isolation circuit between a communication link and the communication interface to improve communication information noise immunity.

13. The module according to claim 7, further comprising isolation between a communication link and the communication interface of the control board to improve noise immunity for communications.

14. The module according to claim 1, further comprising an ADC input on the processor; and
a capacitor between the ADC input and ground sized to prevent loss of significance in a conversion.

15. The module according to claim 7, further comprising electrically isolated voltage supplies referenced to a voltage level in common with the signal processor.

16. The module according to claim 15, wherein the power supply further comprises an adjustable linear regulator, such that all reference voltages track together from the linear regulator.

17. The module according to claim 7, further comprising multiple conductive layers in the control board to increase signal noise immunity and shield the signal processor from noise generated by the power module.

18. The module according to claim 7, wherein the gate driver is powered directly from an input supply voltage.

19. A method for controlling a power inverter having a switch and an output power line with a current sense resistor comprising:
deriving a switch control signal from a processor programmed to command a specific power output;
applying the switch control signal to the switch to produce an output current through the current sense resistor;
measuring a voltage across the current sense resistor;
conditioning the measured voltage signal to provide a conditioned signal indicative of output current to the processor; and
instructing the processor to adjust the switch control signal based on the conditioned signal to obtain a feedback control.

20. The method according to claim 19, further comprising communicating with the processor to provide instructions to command the specific output and process the conditioned signal.
